(19) United States
(12) Patent Application Publication
(10) Pub. No.: US 2019/0044501 A1
(43) Pub. Date: Feb. 7, 2019

(54) HIGH-LINEARITY QUADRATURE HYBRID ATTENUATOR

(71) Applicant: HUAWEI TECHNOLOGIES CO., LTD., Shenzhen (CN)

(72) Inventors: Hakhyun Lee, Montreal (CA); Robert Morawski, Vaudreuil-Dorion (CA); Tho Le-Ngoc, Anjou (CA); James Gary Griffiths, Ontario (CA)

(73) Assignee: HUAWEI TECHNOLOGIES CO., LTD., Shenzhen (CN)

(21) Appl. No.: 15/666,538

(22) Filed: Aug. 1, 2017

(51) Int. Cl. H03H 11/24; H01P 5/18

(52) U.S. Cl. CPC H03H 11/24; H01P 5/18

(57) ABSTRACT

Various arrangements of a PIN diode attenuator circuit are presented. The PIN diode attenuator circuit may include a quadrature hybrid coupler. The PIN diode attenuator circuit may include a direct current (DC) feed circuit comprising an adjustable DC voltage source. PIN diode attenuator circuit may include first and second PIN diode circuits connected with ports of the quadrature hybrid coupler. Each PIN diode circuit may include a PIN diode having a first cathode of the first PIN diode directly connected to a ground potential and a first anode of the first PIN diode connected with the DC feed circuit and the quadrature hybrid coupler.

### BACKGROUND

A programmable attenuator is an important component in various types of adaptive systems. For example, adaptive linear transversal filters, equalizers, canceller circuits, and self-interference cancellers for full-duplex wireless transceivers may each include a programmable attenuator. The programmable attenuator used in such circuits may affect the dynamic range of the whole circuit. For example, non-linear distortion caused by the programmable attenuator can introduce interference that degrades overall performance of such circuits.

### SUMMARY

Various embodiments of PIN diode attenuator circuits are detailed herein. Such a PIN diode attenuator circuit may include a quadrature hybrid coupler that has ports connected with PIN diodes directly connected to ground. Each PIN diode may be biased by a DC voltage generated by a variable DC voltage source. The generated DC voltage creates a bias current through the PIN diodes, which controls the amount of attenuation applied to the RF input signal. Such PIN diode attenuator circuits may be designed to handle a high RF input power while providing linear attenuation. Such an arrangement can handle a high power input signal and has a higher third-order input intercept point (IIP3). Such an arrangement may extend the linear region of the PIN diode, suppress distortion, return loss and reflection may be small.

According to various aspects of the present disclosure, a PIN diode attenuator circuit may be provided. The PIN diode attenuator circuit may include a quadrature hybrid coupler that includes: a first port that functions as an RF input port; a second port that functions as an RF output port; a third port; and a fourth port. The PIN diode attenuator circuit may include a direct current (DC) feed circuit comprising an adjustable DC voltage source. The PIN diode attenuator circuit may include a first PIN diode circuit connected with the third port of the quadrature hybrid coupler. The PIN diode attenuator circuit may include a first PIN diode having a first cathode of the first PIN diode directly connected to a ground potential and a first anode of the first PIN diode connected with the DC feed circuit and the third port of the quadrature hybrid. The PIN diode attenuator circuit may include a second PIN diode circuit connected with the fourth port of the quadrature hybrid. The second PIN diode attenuator circuit may include a second PIN diode having a second cathode of the second PIN diode directly connected to a ground potential and a second anode of the second PIN diode connected with the DC feed circuit and the fourth port of the quadrature hybrid.

Embodiments of such PIN diode attenuator circuits may optionally include one or more of the following features: The PIN diode attenuator circuit may include a first DC blocking circuit connected between the first anode of the first PIN diode and the third port of the quadrature hybrid coupler. The PIN diode attenuator circuit may include a second DC blocking circuit connected between the second anode of the second PIN diode and the fourth port of the quadrature hybrid. The first DC blocking circuit may include a first capacitor in series between the first anode of the first PIN diode and the third port of the quadrature hybrid. The second DC blocking circuit may include a second capacitor in series between the second anode of the second PIN diode and the fourth port of the quadrature hybrid. The DC feed circuit may include a first and second inductor. The DC feed circuit may include: a first resistor, wherein the first inductor and the first resistor are connected in series with the adjustable DC voltage source and the first anode of the first PIN diode; and a second resistor, wherein the second inductor and the second resistor are connected in series with the adjustable DC voltage source and the second anode of the second PIN diode. The entire PIN diode attenuator circuit may include two or fewer resistors.

According to various aspects of the present disclosure, a method for attenuating an RF signal may be presented. The method may include generating, by a variable voltage source, a DC voltage signal, wherein the DC voltage signal induces a bias current through two PIN diode circuits. The method may include receiving, at an RF input port of a quadrature hybrid coupler, an RF input signal to be attenuated. The method may include transmitting, the RF input signal to a first PIN diode circuit and a second PIN diode circuit, wherein a first PIN diode of the first PIN diode circuit and a second PIN diode of the second PIN diode circuit are connected directly to ground. The method may include reflecting the RF input signal in an attenuated form to produce an attenuated RF signal. The method may include outputting, through an RF output port of the quadrature hybrid coupler, the attenuated RF signal.

Optionally, two or fewer resistors may be part of the circuit that performs attenuation of the RF input signal. Optionally, the RF input signal may be passed through a DC blocking circuit to remove a DC component of the RF input signal.

### BRIEF DESCRIPTION OF THE DRAWINGS

FIG. 1 illustrates an embodiment of a block diagram of a programmable attenuator.

FIG. 2 illustrates an embodiment of a circuit diagram of a programmable attenuator.

FIG. 3 illustrates a graph of the third-order input intercept point (IIP3) against the control current for an embodiment of the programmable attenuator.

FIG. 4 illustrates a graph of control voltage against IIP3 of an embodiment of a programmable attenuator.

FIG. 5 illustrates a graph of S11 at an RF input port of an embodiment of a programmable attenuator against frequency as a function of the control voltage output by the adjustable voltage source.

FIG. 6 illustrates a graph of S21 of an embodiment of a programmable attenuator circuit against frequency as a function of the control voltage output by the adjustable voltage source.

FIG. 7 illustrates a graph of attenuation at 2.2 GHz against control voltage for an embodiment of a programmable attenuator.

FIG. 8 illustrates an embodiment of a method for attenuating an RF signal using a programmable attenuator.

### DETAILED DESCRIPTION

While many attenuator circuits are designed for low current consumption, such attenuator circuits may be susceptible to a large amount of non-linear inter-modulation distortion (IMD) being created by a relatively high power input signal. A hybrid quadrature coupler coupled with PIN diodes that have cathodes connected directly to ground can have several advantages. Such an arrangement can handle a high power input signal and has a higher third-order intercept point (IIP3). Such an arrangement can extend the linear region of the PIN diode, suppress distortion, return loss and reflection may be low. Further, the scattering parameters of such a circuit over a wide bandwidth, such as around 1 GHz in bandwidth, may be desirable. In order to be able to handle a high power input signal, each component of such a programmable attenuator may handle at least 55 dBm for the IIP3.

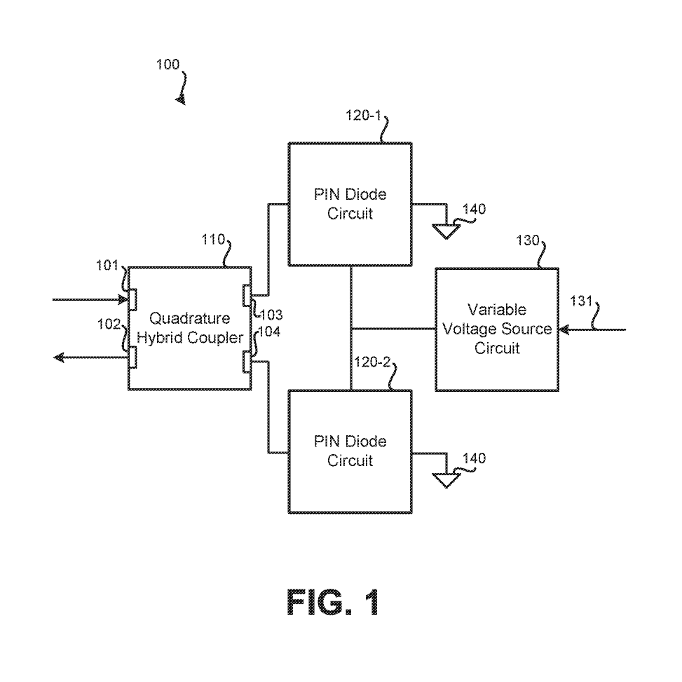

FIG. 1 illustrates an embodiment of a block diagram of a programmable attenuator circuit 100 that uses a quadrature hybrid coupler. Programmable attenuator circuit 100 may include: quadrature hybrid coupler 110; two PIN diode circuits 120 (120-1 and 120-2); and a variable voltage source 130.

Quadrature hybrid coupler 110 includes four ports, including an RF input port 101 and RF output port 102. The input and output roles of RF input port 101 and RF output port 102 may be switched. Quadrature hybrid coupler 110 may be a 3 dB, 90° coupler. As an example, the X3C22E1-03S ANAREN RF Hybrid Coupler may be used as quadrature hybrid coupler 110. In other embodiments of programmable attenuator circuit 100, another form of coupler may be used, such as a 90° or 180° three port coupler.

A third port 103 of quadrature hybrid coupler 110 may be connected with PIN diode circuit 120-1 and a fourth port 104 of quadrature hybrid coupler 110 may be connected with PIN diode circuit 120-2. PIN diode circuits 120-1 and 120-2 may be separate and distinct from each other. Each of PIN diode circuits 120 may include a PIN diode. A PIN diode has an undoped intrinsic semiconductor region between a p-type semiconductor region and an n-type semiconductor region. As a bias current applied to a PIN diode increases, the high frequency resistivity of the PIN diode decreases. Each PIN diode within each PIN diode circuit of PIN diode circuits 120 may be connected directly to ground. By connecting each PIN diode directly to ground 140 without a series resistor, a large amount of heat that would be dissipated by a low resistance resistor can be avoided if the power of the RF input signal on the RF input port 101 is high.

There can be additional advantages to having each PIN diode connected directly to ground. If a PIN diode is connected to a resistor which is then connected to ground, there may be no reflection back to the output RF port due to the resistance of the resistor being matched to the input port impedance. Also, such an extra resistor can dissipate heat when current moves through it. In embodiments detailed herein, by removing any resistors between the PIN diode and ground, the PIN diode-to-ground impedance is removed, thus resulting in a low RF impedance and in a high linearity attenuation region of the circuit when a bias current is applied to the PIN diode.

Variable voltage source 130 may receive an input (e.g., voltage input control signal 131) that causes a voltage output by variable voltage source 130 to vary. Variable voltage source 130 may output a same voltage to both PIN diode circuits 120. The amount of voltage output by variable voltage source 130 affects the biasing current applied to each PIN diode of PIN diode circuits 120. The greater the biasing current applied, the lower the resistance of the PIN diode circuits, the lesser amount of attenuation performed on the RF input signal received via RF input port 101. That is, the greater the biasing current applied to each PIN diode within PIN diode circuits 120, the resistivity of each PIN diode decreases, decreasing attenuation.

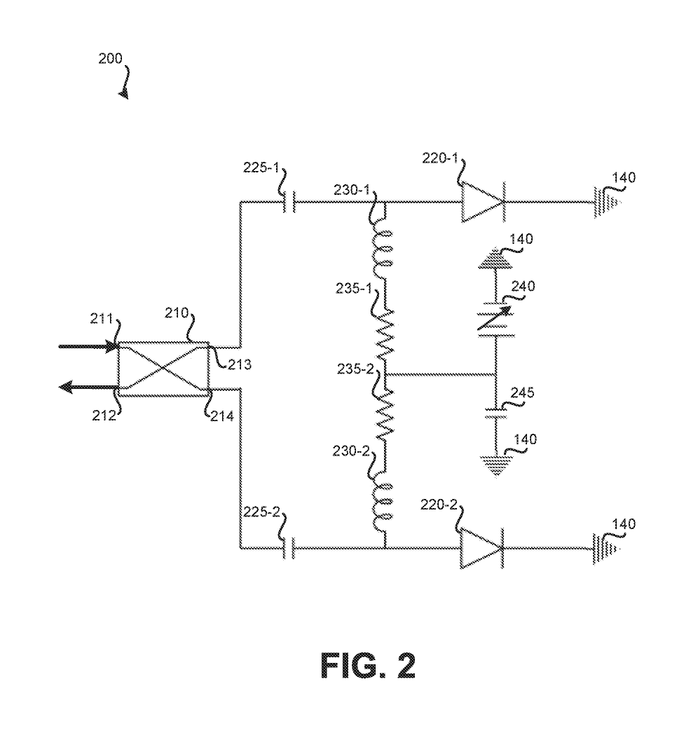

FIG. 2 illustrates an embodiment of a circuit diagram of a programmable attenuator circuit 200. Programmable attenuator circuit 200 can represent an embodiment of programmable attenuator circuit 100 of FIG. 1. Programmable attenuator circuit 200 may include: quadrature hybrid coupler 210 (having RF input port 211, RF output port 212, third port 213, and fourth port 214); PIN diodes 220 (220-1, 220-2); capacitors 225 (225-1, 225-2); inductors 230 (230-1, 230-2); resistors 235 (235-1, 235-2); variable voltage source 240; capacitor 245; and ground 140.

It should be understood that in some embodiments of programmable attenuator circuit 200 it may be desirable to minimize the number of components. Keeping the number of components low can decrease the total cost of manufacturing programmable attenuator circuit 200 and/or can decrease the amount of power consumed by programmable attenuator circuit 200. If the RF input signal applied to RF input port 211 is high, an amount of heat may be dissipated by components of programmable attenuator circuit 200 through which current passes. For example, by not having resistors between PIN diodes 220 and ground, heat is not generated by the nonexistent resistors. Programmable attenuator circuit 200 may include exactly two (or fewer) resistors 235. Programmable attenuator circuit 200 may include exactly two PIN diodes 220.

Quadrature hybrid coupler 210 may function as detailed in relation to quadrature hybrid coupler 110 of FIG. 1. Again here, the input and output roles of RF input port 211 and RF output port 212 can be reversed. Third port 213 and fourth port 214 may be connected with DC blocking circuits. In programmable attenuator circuit 200, capacitor 225-1, arranged in series with PIN diode 220-1, serves as a DC blocking circuit for third port 213 and capacitor 225-2, arranged in series with PIN diode 220-2, serves as a DC blocking circuit for fourth port 214. These DC blocking circuits can prevent a DC component of an RF input signal applied to RF input port 211 from passing through the remainder of the programmable attenuator circuit 200. In some embodiments, 3.7 pF capacitors may be used for capacitors 225. Different capacitance values for capacitors 225 may be used (e.g., a similar or higher capacitance); however it may be beneficial for the capacitor impedance to be below 10Ω for the desired frequency range (e.g., 1.7 GHz to 2.7 GHz).

PIN diode 220-1 may represent PIN diode circuit 120-1 of FIG. 1 and PIN diode 220-2 may represent PIN diode circuit 120-2. The cathodes of PIN diodes 220-1 and 220-2 may be connected directly to ground 140. Therefore, no other component, such as a resistor, may be connected between the cathodes of PIN diodes 220 and ground 140. The anode of PIN diode 220-1 may be connected with capacitor 225-1 and the anode of PIN diode 220-2 may be connected with capacitor 225-2.

Also connected with the anode of PIN diodes 220 may be a variable voltage source circuit, which is represented in FIG. 1 as variable voltage source 130. The variable voltage source circuit may include a variable voltage source 240 that is controlled by an external input. Only a single variable voltage source 240 may be used for programmable attenuator circuit 200. For example, the voltage may be varied in a range of between 0.8 V and 8 V depending on the desired amount of attenuation. The greater the voltage output, the greater the bias current applied to the PIN diodes, the lesser the attenuation. Variable voltage source 240 may be connected with capacitor 245 in parallel. Capacitor 245 may help even the amount of current output to PIN diodes 220 in the case of a sudden current draw from variable voltage source 240. Capacitor 245 may have a capacitance of 1000 pF. In other embodiments, the capacitance of capacitor 245 may vary between 10 pF and 47 uF.

The voltage created by variable voltage source 240 may be provided to two combinations of resistors and inductors. These resistors and inductors create two DC paths for the biasing voltage created by variable voltage source 240 to be applied to PIN diodes 220-1. Resistors 235 may each have a value of 150Ω and inductors 230 may each have a value of 43 nH. The resistance of resistors 235 may be based on the characteristics of PIN diodes used for PIN diodes 220. In some embodiments, resistors 235 may each have a same value and may fall with a range of 40-400Ω. In some embodiments, inductors 230 may each have a value falling in the range of 20-200 nH. In some embodiments, it may be possible to replace resistors 235 with a single resistor that is connected with both of inductors 230 and variable voltage source 240. Inductors 230 may help prevent the RF signal from entering the variable DC circuit. The DC voltage output by variable voltage source 240 creates a biasing current through PIN diodes 220, which reduces the resistivity of PIN diodes 220, thereby decreasing the attenuation of the input RF signal received via RF input port 211. For example, a 1 mA bias current applied to PIN diode 220-1 or 220-2 (based on the voltage output by variable voltage source 240) may cause its impedance to be 42.6Ω, while a 100 mA bias current applied to PIN diode 220-1 or 220-2 may cause its impedance to be 3Ω. More specifically, the resistance of a PIN diode is defined by equation 1:

$${R}_{S} = \frac{{W}^{2}}{( {μ}_{N} + {μ}_{P} ) {I}_{F} τ} . \qquad Eq . 1$$

In equation 1, R_{S} is the resistance of the PIN diode, W is the width of the PIN diode's intrinsic region, μ_{N} is electron mobility, μ_{P} is hole mobility, τ is the carrier lifetime, and I_{F} is the forward bias current. Except for I_{F}, each of these characteristics is a fixed property of the PIN diode. As such, to vary the resistance of a PIN diode, I_{F} is varied by adjusting the output voltage of variable voltage source 240.

When used for attenuation, such as in programmable attenuator circuit 200, the third-order inter-modulation distortion of a PIN diode can be an important consideration. IIP3, the third order inter-modulation distortion can be calculated according to equation 2:

$$IP 3 = \frac{{F}_{MHz} {I}_{{F}^{2} {τ}^{2}} ( {μ}_{N} + {μ}_{P} )}{{W}^{2}} [ dBm ] . \qquad Eq . 2$$

For PIN diodes 220, the BROADCOM HSMP-4810 may be used. This model PIN diode may exhibit 3Ω of resistance at 100 mA of biasing current (at 100 MHz). In other embodiments, a different make and/or model of PIN diode may be used that could have different characteristics.

Programmable attenuator circuit 200 may be matched to a particular impedance, such as 50Ω. Similarly, the RF input and output lines connected with RF input port 211 and RF output port 212 may have an impedance of 50Ω. By having both sides of the programmable attenuator circuit 200 matched to 50Ω, the RF input signal may not be reflected back to the RF output port.

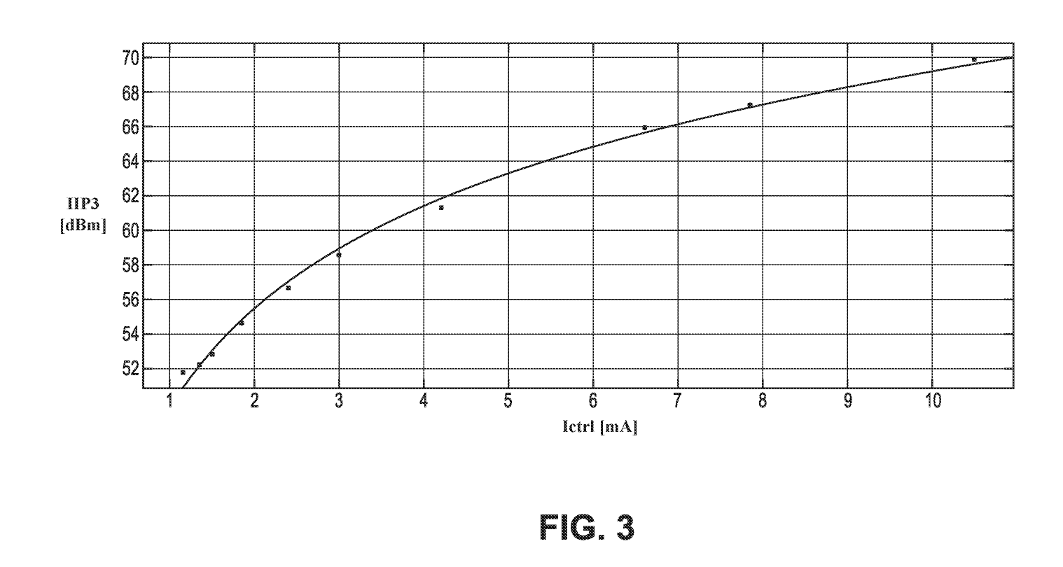

Using the specific component values detailed in relation to FIG. 2, including: X3C22E1-03S ANAREN RF Hybrid Coupler as quadrature hybrid coupler 210, 3.7 pF capacitors as capacitors 225, a 1000 pF capacitor as capacitor 245, 150 Ohm resistors as resistors 235, and 43 nH inductors as inductors 230, favorable characteristics of programmable attenuator circuit 200 may be realized. Such operating characteristics can include: S11 of −20 dB, an insertion loss (IL) of −1.6 dB, a maximum attenuation of 18 dB, and an IIP3 of 51-74 dB. When used on an RF input signal having a frequency between 1.7 GHz and 2.7 GHz, S11 may be less than −20 dB, a voltage standing wave ratio (VSWR) of less than 1.22. When used on an RF input signal having a frequency between 1.3 GHz and 3.5 GHz, S11 may be less than −14 dB and VSWR may be less than 1.5. Further performance data of such an embodiment of programmable attenuator circuit 200 is provided in relation to FIGS. 3-7.

FIG. 3 illustrates a graph of the third-order intercept point (IIP3) against the control current for an embodiment of the programmable attenuator. FIG. 3 illustrates a curve that has been fit to gathered data points. For FIG. 3, the IIP3 measurements were made at 2.1 GHz. The control current is measured passing through a resistor of resistors 235 (therefore, the total current output by the variable voltage source 240 is double the control current). As the control voltage output by the variable voltage source is adjusted, the IIP3 increases from 51 to 74 dBm. Despite this high IIP3 range, the insertion loss on the programmable attenuator circuit 200 may be −1.6 dB or less than −2.0 dB. In some embodiments, if 55 dBm is the desired lower limit for the IIP3, a 2 mA Ictrl current and greater will be sufficient.

For certain applications, having an IIP3 of at least 55 dBm may be advisable. For example, a full-duplex transceiver may have a transmit power of 30 dBm and a receiver sensitivity of −80 dBm. The attenuator input power (Pᵢₐ) is typically in the 0-10 dBm range. The minimum required two-tone third-order intermodulation distortion (IMD3) would be 90 dBc (based on the receive power being subtracted from the attenuator input power). IIP3, which can be defined in accordance with equation 3 below, would thus represent the minimum required IIP3 to avoid adding inter-modulation distortions. Thus, if Pᵢₐ is 10 dBm, IIP3 would be 55 dBm. Programmable attenuator circuit 200 achieves such a desired IIP3.

$$IIP 3 = {P}_{ia} + \frac{IMD 3}{2} \qquad Eq . 3$$

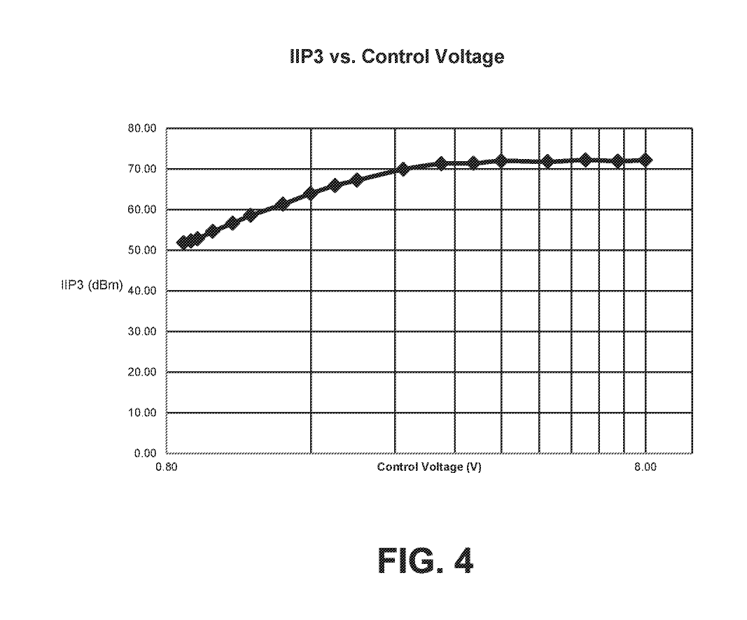

FIG. 4 illustrates a graph of control voltage in Volts against IIP3 in dBm of an embodiment of programmable attenuator circuit 200. The control voltage represents the voltage output by variable voltage source 240. As can be seen here, for the component values specified, the IIP3 ranges between 51-74 dBm as the control voltage is varied from 0.81 V to 8 V.

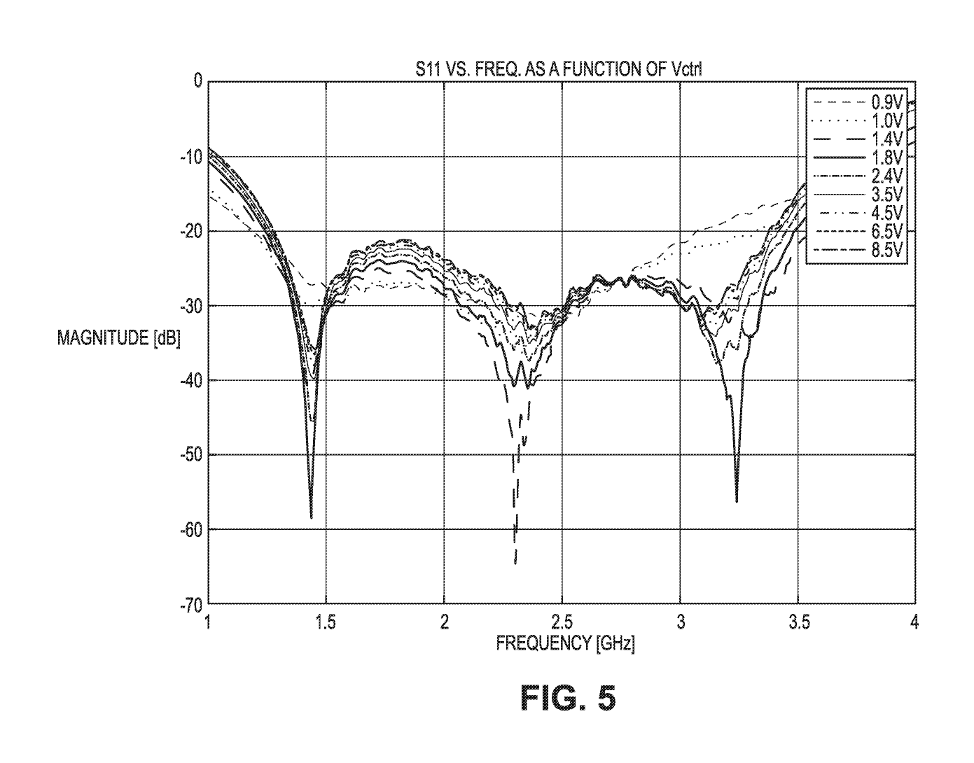

FIG. 5 illustrates a graph of S11 at RF input port 211 of programmable attenuator circuit 200 against frequency as a function of the control voltage output by the adjustable voltage source for the embodiment of programmable attenuator circuit 200 illustrated in FIG. 2. As can be seen, S11 remains low and roughly consistent for all voltages, especially when a frequency of roughly 2.1 GHz is used for the RF input signal. Within the range of 1.3 to 3 GHz, S11 remains below −20 dB.

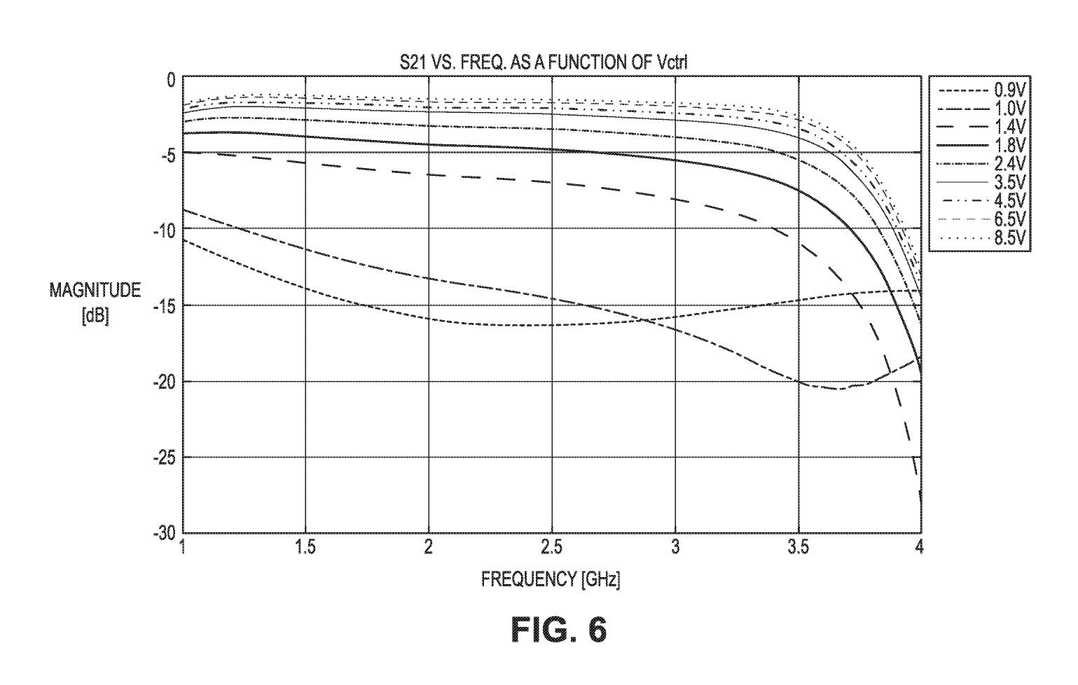

FIG. 6 illustrates a graph of S21 against frequency as a function of the control voltage output by the adjustable voltage source for the embodiment of programmable attenuator circuit 200 of FIG. 2. S21 remains above −2 dB for 8.5 Vn the range 1-3 GHz. Between 1.3 and 4 GHz, S21 remains below −10 dB when the control voltage is at most 1.0 V.

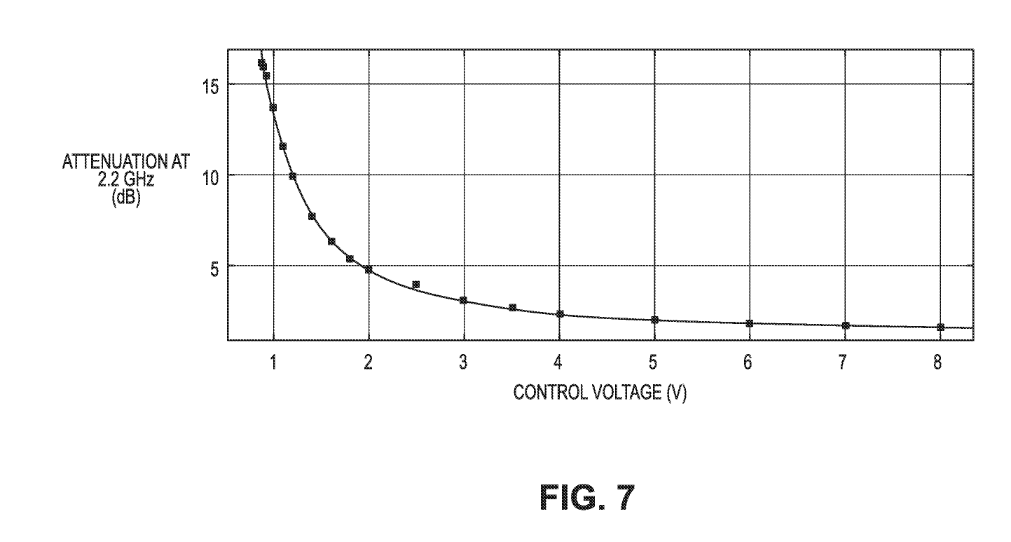

FIG. 7 illustrates a graph of attenuation at 2.2 GHz against control voltage for the embodiment of programmable attenuator circuit 200 of FIG. 2. The curve illustrated is a best fit curve to the data points obtained using an embodiment of programmable attenuator circuit 200.

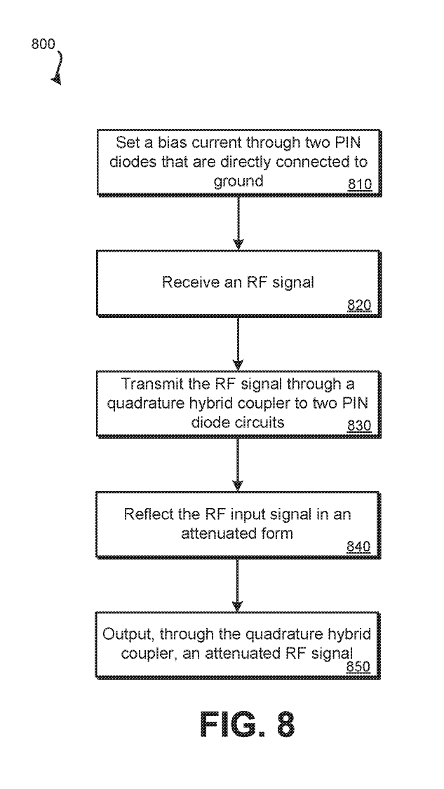

FIG. 8 illustrates an embodiment of a method 800 for attenuating an RF signal using a programmable attenuator. The programmable attenuator used in method 800 may be the programmable attenuator of FIG. 1 or FIG. 2. At block 810, a variable voltage source may be used to create a bias current through a pair of PIN diodes. The greater the bias current applied to the two PIN diodes, the lesser the resistance of the PIN diodes, and thus, the lesser the amount of attenuation applied to an RF input signal by the PIN diodes. The voltage generated by the variable voltage source may be programmed or set by an external source. For example, the variable voltage source may be in communication with a controller, processor, or other circuitry that provides a control signal to the variable voltage source. This control signal may cause the variable voltage source to vary its output voltage.

At block 820, an RF input signal may be received through a port of a quadrature hybrid coupler. This received RF input signal represents an RF signal that is to be attenuated by some amount. Another circuit or device may determine the amount of attenuation to be applied to the received RF input signal. This other circuit or device may control the amount of attenuation to be performed based on the control signal supplied to the variable voltage source of the programmable attenuator.

At block 830, the input RF signal may pass to the two PIN diode circuits through two DC blocking circuits. The two DC blocking circuits can block a DC component, if present, of the RF input signal. This DC blocking circuit helps to prevent the bias current being applied to the PIN diodes from being inadvertently increased and, thus, affecting attenuation.

At block 840, the RF input signal is reflected by the PIN diode circuits to create an attenuated RF output signal. The magnitude of reflection is based on the resistivity of the PIN diodes. As such, the amount of bias current generated by the variable DC voltage source will effectively control the amount of attenuation between the reflected attenuated RF output signal and the RF input signal. At block 850, the attenuated RF output signal may be output through the quadrature hybrid coupler via an RF output port.

The methods, systems, and devices discussed above are examples. Various configurations may omit, substitute, or add various procedures or components as appropriate. For instance, in alternative configurations, the methods may be performed in an order different from that described, and/or various stages may be added, omitted, and/or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations will provide those skilled in the art with an enabling description for implementing described techniques. Various changes may be made in the function and arrangement of elements without departing from the spirit or scope of the disclosure.

Also, configurations may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure. Furthermore, examples of the methods may be implemented by hardware, software, firmware, middleware, microcode, hardware description languages, or any combination thereof. When implemented in software, firmware, middleware, or microcode, the program code or code segments to perform the necessary tasks may be stored in a non-transitory computer-readable medium such as a storage medium. Processors may perform the described tasks.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of steps may be undertaken before, during, or after the above elements are considered.

1.-11. (canceled)

12. A method for attenuating a radio frequency (RF) signal in a programmable attenuator circuit, the method comprising:
receiving an RF input signal over an RF input port of a quadrature hybrid coupler in the programmable attenuator circuit, the quadrature hybrid coupler including the RF input port, an RF output port, a third port, and a fourth port;
generating, by a variable voltage source, a direct current (DC) voltage signal for biasing two PIN diodes coupled to the third port and the fourth port of the quadrature hybrid coupler, wherein a magnitude of the DC voltage signal is set to induce at least a threshold bias current through each of the two PIN diodes such that an impedance through each of the two PIN diodes is less than a characteristic impedance of the programmable attenuator circuit;
attenuating the RF input signal via the programmable attenuator circuit; and
outputting the attenuated RF signal over the RF output port of the quadrature hybrid coupler.

13. The method of claim 12, further comprising:
passing the RF input signal through a DC blocking circuit to remove a DC component of the RF input signal.

14. The method of claim 13, wherein the DC blocking circuit comprises a capacitor in series between one of the two PIN diodes.

15. The method of claim 12, wherein the variable voltage source is part of a DC voltage circuit that includes a first inductor, a first resistor, a second inductor, and a second resistor, wherein the first inductor and the first resistor are connected in series with the variable voltage source and a first one of the two PIN diodes, and wherein the second inductor and the second resistor are connected in series with the variable voltage source and a second one of the two PIN diodes.

16. The method of claim 15, wherein the first resistor and the second resistor are the only resistors present in a circuit that attenuates the RF input signal.

17. The method of claim 16, wherein the first resistor and the second resistor each have a resistance value in a range of 40Ω to 400Ω.

18. The method of claim 12, wherein the quadrature hybrid coupler is a 90°, 3 dB quadrature hybrid coupler having an insertion loss of less than 0.2 dB and isolation of at least 20 dB.

19. The method of claim 12, wherein the two PIN diodes are matched to 50Ω.

20. The method of claim 12, wherein the variable voltage source supplies current in a range of 1 mA to 100 mA to each of the two PIN diodes.

21-31. (canceled)

32. An apparatus comprising:
a processor; and
a non-transitory computer readable storage medium storing programming for execution by the processor, the programming including instructions to:
receive an RF input signal over an RF input port of a quadrature hybrid coupler in the programmable attenuator circuit, the quadrature hybrid coupler including the RF input port, an RF output port, a third port, and a fourth port;
generate, by a variable voltage source, a direct current (DC) voltage signal for biasing two PIN diodes coupled to the third port and the fourth port of the quadrature hybrid coupler, wherein a magnitude of the DC voltage signal is set to induce at least a threshold bias current through each of the two PIN diodes such that an impedance through each of the two PIN diodes is less than a characteristic impedance of the programmable attenuator circuit;
attenuate the RF input signal via the programmable attenuator circuit; and
output the attenuated RF signal over the RF output port of the quadrature hybrid coupler.

33. The apparatus of claim 32, wherein the programming further includes instructions to:
pass the RF input signal through a DC blocking circuit to remove a DC component of the RF input signal.

34. The apparatus of claim 33, wherein the DC blocking circuit comprises a capacitor in series between one of the two PIN diodes.

35. The apparatus of claim 32, wherein the variable voltage source is part of a DC voltage circuit comprising a first inductor, a first resistor, a second inductor, and a second resistor, wherein the first inductor and the first resistor are connected in series with the variable voltage source and a first one of the two PIN diodes, and wherein the second inductor and the second resistor are connected in series with the variable voltage source and a second one of the two PIN diodes.

36. The apparatus of claim 35, wherein the first resistor and the second resistor are the only resistors present in a circuit that attenuates the RF input signal.

37. The apparatus of claim 35, wherein the first resistor and the second resistor each have a resistance value in a range of 40Ω to 400Ω.

38. The apparatus of claim 32, wherein the quadrature hybrid coupler is a 90°, 3 dB quadrature hybrid coupler having an insertion loss of less than 0.2 dB and isolation of at least 20 dB.

39. The apparatus of claim 32, wherein the two PIN diodes are matched to 50Ω.

40. The apparatus of claim 32, wherein the variable voltage source supplies current in a range of 1 mA to 100 mA to each of the two PIN diodes.

41. A computer program product comprising a non-transitory computer readable storage medium storing programming, the programming including instructions to:
receive an RF input signal over an RF input port of a quadrature hybrid coupler in the programmable attenuator circuit, the quadrature hybrid coupler including the RF input port, an RF output port, a third port, and a fourth port;
generate, by a variable voltage source, a direct current (DC) voltage signal for biasing two PIN diodes coupled to the third port and the fourth port of the quadrature hybrid coupler, wherein a magnitude of the DC voltage signal is set to induce at least a threshold bias current through each of the two PIN diodes such that an impedance through each of the two PIN diodes is less than a characteristic impedance of the programmable attenuator circuit;
attenuate the RF input signal via the programmable attenuator circuit; and
output the attenuated RF signal over the RF output port of the quadrature hybrid coupler.

42. The apparatus of claim 41, wherein the programming further includes instructions to:
pass the RF input signal through a DC blocking circuit to remove a DC component of the RF input signal.
